(19) United States
(12) Patent Application Publication
(10) Pub. No.: US 2007/0041351 A1
(43) Pub. Date: Feb. 22, 2007

(54) Method and system effecting communications in a wireless communication network

(75) Inventors: Mousumi Hazra, Beaverton, OR (US); W. Steven Conner, Hillsboro, OR (US); Mark D. Yarvis, Santa Clara, CA (US)

Correspondence Address: LAW OFFICE OF DONALD D. MONDUL;c/o INTELLEVATE, P.O. BOX 52050, MINNEAPOLIS, MN, 55402, US

(73) Assignee: Intel Corporation

(21) Appl. No.: 11/205,857

(22) Filed: Aug. 17, 2005

(51) Int. Cl. G01R 31/08; H04Q 7/24

(52) U.S. Cl. 370/338; 370/252; 455/452.2

(57) ABSTRACT

Briefly, in accordance with one embodiment of the invention, a method effecting communications in a wireless communication network including mobile stations and a base station comprising: (a) in no particular order: (1) operating a first mobile to effect a first evaluation of a first communication link between the first mobile and a second mobile; (2) operating the first mobile to effect a second evaluation of a second communication link between the base station and the first mobile; and (3) operating the base station to effect a third evaluation of a third communication link between the base station and the second mobile; (b) collecting information relating to the evaluations at the first mobile; and (c) operating the first mobile to employ the evaluations to select at least one selected communication link from among the communication links to establish a communication route between the first mobile and the second mobile.

### BACKGROUND

Generally in the past mobile stations in a base station system for wireless communication are not permitted to communicate directly with other mobile communication stations. Instead, mobile stations have been required to relay communications via an access point (also sometimes referred to as a base station). Wireless networking hardware requires the use of underlying technology that deals with radio frequencies as well as data transmission. The most widely used standard is 802.11 produced by the Institute of Electrical and Electronic Engineers (IEEE). This is a standard defining all aspects of Radio Frequency Wireless networking.

A subset of 802.11 is 802.11e which specifies a direct link setup (DLS) protocol for establishing a direct link (DL) between two stations. The DLS protocol permits mobile communication stations in a mobile communication system such as a BSS network to communicate directly with each other or to communicate indirectly via an access point. However, the 802.11e standard does not specify a mechanism for choosing between a direct link and an indirect link.

There is a need for a method and system for dynamically evaluating communication link conditions and advantageously selecting a direct link or an indirect link for communication between two mobile stations.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a schematic diagram illustrating a system configured for employing the present invention;

FIG. 2 is a schematic representation of a protocol for the method of the present invention; and

FIG. 3 is a flow chart illustrating the method of the present invention.

It will be appreciated that for simplicity and clarity of illustration, elements illustrated in the figures have not necessarily been drawn to scale. For example, the dimensions of some of the elements are exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

Some portions of the detailed description that follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Embodiments of the present invention may include apparatuses for performing the operations herein. An apparatus may be specially constructed for the desired purposes, or it may comprise a general purpose computing device selectively activated or reconfigured by a program stored in the device. Such a program may be stored on a storage medium, such as, but not limited to, any type of disk including floppy disks, optical disks, compact disc read only memories (CD-ROMs), magnetic-optical disks, read-only memories (ROMs), random access memories (RAMs), electrically programmable read-only memories (EPROMs), electrically erasable and programmable read only memories (EEPROMs), magnetic or optical cards, or any other type of media suitable for storing electronic instructions, and capable of being coupled to a system bus for a computing device.

The processes and displays presented herein are not inherently related to any particular computing device or other apparatus. Various general purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the invention as described herein. In addition, it should be understood that operations, capabilities, and features described herein may be implemented with any combination of hardware (discrete or integrated circuits) and software.

Use of the terms “coupled” and “connected”, along with their derivatives, may be used. It should be understood that these terms are not intended as synonyms for each other. Rather, in particular embodiments, “connected” may be used to indicate that two or more elements are in direct physical or electrical contact with each other. “Coupled” my be used to indicated that two or more elements are in either direct or indirect (with other intervening elements between them) physical or electrical contact with each other, and/or that the two or more elements co-operate or interact with each other (e.g. as in a cause an effect relationship).

It should be understood that embodiments of the present invention may be used in a variety of applications. Although the present invention is not limited in this respect, the devices disclosed herein may be used in many apparatuses such as in the transmitters and receivers of a radio system. Radio systems intended to be included within the scope of the present invention include, by way of example only, cellular radiotelephone communication systems, satellite communication systems, two-way radio communication systems, one-way pagers, two-way pagers, personal communication systems (PCS), personal digital assistants (PDA's), wireless local area networks (WLAN), personal area networks (PAN, and the like).

Types of cellular radiotelephone communication systems intended to be within the scope of the present invention include, although not limited to, Code Division Multiple Access (CDMA) cellular radiotelephone communication systems, Global System for Mobile Communications (GSM) cellular radiotelephone systems, North American Digital Cellular (NADC) cellular radiotelephone systems, Time Division Multiple Access (TDMA) systems, Extended-TDMA (E-TDMA) cellular radiotelephone systems, third generation (3G) systems like Wide-band CDMA (WCDMA), CDMA-2000, and the like.

As mentioned earlier herein, IEEE Standard 802.11e specifies a Direct Link Setup (DLS) protocol for creating a direct link (DL) between mobile stations for communication without involvement by an access point. DLS allows an access point to continue to act on behalf of a mobile station in a power-save mode. Once the mobile station has been awakened by the access point, direct transmission to the mobile station is allowed once again. DLS also permits an access point to assist in an exchange of rate set and other information between an originating station and a receiving station, such as between two mobile stations.

To make an informed selection between communicating via a direct link (DL) or via an indirect link (i.e., involving an access point), an originating mobile station must anticipate performance aspects, such as capacity and quality, of the direct link vis-à-vis the indirect link before traffic flow commences. Consequences of an incorrect selection between a DL and an indirect link may cause a high frame loss rate, a high re-transmission rate or other inefficiencies that may adversely affect throughput of the communication link established as well as net aggregate throughput of the entire network.

One approach may be to simply choose a direct link and begin sending traffic to a receiver mobile station. If poor performance is detected one may then switch to an indirect link for communications, and may perhaps need to switch back again later until the best choice of communication link is found. Such switching back and forth is not efficient, may give a user unpleasant latency in communication and may cause jitter in communications. These conditions should be avoided.

An intelligent choice between a DL and an indirect link requires an informed estimate of the relative throughput and reliability (and perhaps other factors).

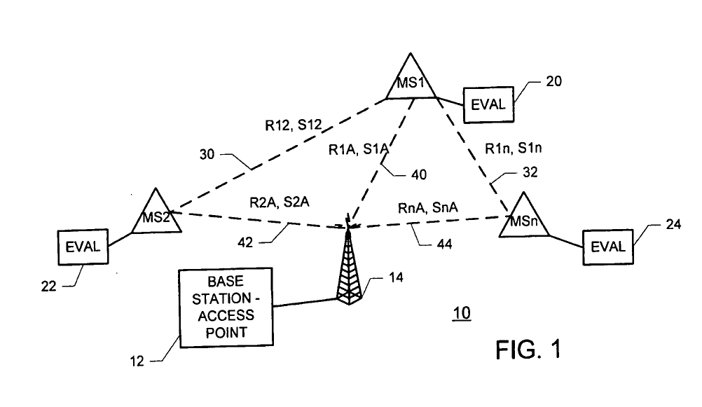

FIG. 1 is a schematic diagram illustrating a system configured for employing the present invention. In FIG. 1, a communication system 10 includes a base station or access point 12, an antenna or communication tower 14 coupled with access point 12, a first mobile station MS₁, a second mobile station MS₂ and a third mobile station MSₙ. The indicator “n” is employed to signify that there can be any number of mobile stations in communication system 10. There may be more than one access point 12 in communication system 10. The inclusion of one access point 12 and three mobile stations MS₁, MS₂, MSₙ in FIG. 1 is illustrative only and does not constitute any limitation regarding the number of mobile stations or access points that may be included in a communication system using the present invention.

A first evaluation unit 20 is coupled with first mobile station MS₁. A second evaluation unit 22 is coupled with second mobile station MS₂. A third evaluation unit 24 is coupled with third mobile station MSₙ. Any of evaluation units 20, 22, 24 may be integrally included in a respective mobile station MS₁, MS₂, MSₙ or may be configured for external connection with a respective mobile station MS₁, MS₂, MSₙ. Access point 12 may integrally include or have coupled thereto an evaluation unit (not shown in FIG. 1). An evaluation unit at any locus (i.e., a mobile station MS₁, MS₂, MSₙ or access point 12) may handle all evaluations described herein and provide solutions or conclusions to any respective locus or loci in communication system 10. An evaluation unit may be established outside communication system 10 to service more than one communication system (not shown in FIG. 1). Such an external evaluation unit may be coupled to any or all of loci (i.e., a mobile station MS₁, MS₂, MSₙ or access point 12) within communication system 10 to provide evaluation functions as described herein.

First mobile station MS₁ and second mobile station MS₂ may communicate using a direct link, indicated by a dotted line 30. First mobile station MS₁ and third mobile station MSₙ may communicate using a direct link, indicated by a dotted line 32. First mobile station MS₁ may communicate with access point 12 via a communication link 40. Second mobile station MS₂ may communicate with access point 12 via a communication link 42. Third mobile station MSₙ may communicate with access point 12 via a communication link 44. One may observe that first mobile station MS₁ may also communicate with second mobile station MS₂ via an indirect communication link that includes communication links 40, 42. One may also observe that first mobile station MS₁ may also communicate with third mobile station MSₙ via an indirect communication link that includes communication links 40, 44.

To permit an informed selection between efficacy of using a direct link 30, 32 or an indirect link (40, 42), (40, 44) for communicating between two of mobile stations MS₁, MS₂, MSₙ, an estimate of relative quality of the alternate communication links must be made. The parameters measured in the illustrative example below are representative only. Other parameters may be measured relating to links 30, 40, 42 to effect an evaluation of relative communication link efficiency, link throughput or one or more other link characteristics for evaluating whether to employ direct link 30 or indirect link (40, 42) for communicating between mobile stations MS₁, MS₂. By way of example and not by way of limitation, in FIG. 1,
R_{1A} is the best achievable throughput between first mobile station MS₁ and access point 12.
N_{1A} Is the number of packets included in a given communication between first mobile station MS₁ and access point 12.
S_{1A} is the success rate of communications between first mobile station MS₁ and access point 12.

$${S}_{1 A} = \frac{1}{{N}_{1 A}} .$$
R₁₂ is the best achievable throughput between first mobile station MS₁ and second mobile station MS₂.
N₁₂ Is the number of packets included in a given communication between first mobile station MS₁ and second mobile station MS₂.
S₁₂ is the success rate of communications between first mobile station MS₁ and second mobile station MS₂.

$${S}_{12} = \frac{1}{{N}_{12}} .$$
R₁ₙ is the best achievable throughput between first mobile station MS₁ and third mobile station MSₙ.
N₁ₙ Is the number of packets included in a given communication between first mobile station MS₁ and third mobile station MSₙ.
S₁ₙ is the success rate of communications between first mobile station MS₁ and third mobile station MSₙ.

$${S}_{1 n} = \frac{1}{{N}_{1 n}} .$$
R_{2A} is the best achievable throughput between second mobile station MS₂ and access point 12.
N_{2A} Is the number of packets included in a given communication between second mobile station MS₂ and access point 12.
S_{2A} is the success rate of communications between second mobile station MS₂ and access point 12.

$${S}_{2 A} = \frac{1}{{N}_{2 A}} .$$
R_{nA} is the best achievable throughput between third mobile station MSₙ and access point 12.
N_{nA} Is the number of packets included in a given communication between third mobile station MSₙ and access point 12.
S_{nA} is the success rate of communications between third mobile station MSₙ and access point 12.

$${S}_{nA} = \frac{1}{{A}_{nA}} .$$

The term “success rate” refers to the average number of transmissions required (including retransmissions) to successfully communicate a packet. Success rate S is equal with the inverse of number of packets N:

$$S = \frac{1}{N} \qquad [ 1 ]$$

Using the above established terms:

Average air time T_{1A} for packets having average packet size P communicated between first mobile station MS₁ and access point 12 via link 40:

$${T}_{1 A} = \frac{( P \cdot {N}_{1 A} )}{{R}_{1 A}} \qquad [ 2 ]$$

Average air time T_{2A} for packets having average packet size P communicated between first mobile station MS₂ and access point 12 via link 42:

$${T}_{2 A} = \frac{( P \cdot {N}_{2 A} )}{{R}_{2 A}} . \qquad [ 3 ]$$

Average air time T_{1A2} for packets having average packet size P communicated between first mobile station MS₁ and second mobile station MS₂ via indirect link (40, 42) that includes access point 12:

$${T}_{1 A 2} = {T}_{1 A} + {T}_{2 A} \\ ∴ {T}_{1 A 2} = \frac{( P \cdot {N}_{1 A} )}{{R}_{1 A}} + \frac{( P \cdot {N}_{2 A} )}{{R}_{2 A}} \qquad [ 4 ]$$

Average air time T₁₂ for packets having average packet size P communicated between first mobile station MS₁ and second mobile station MS₂ via direct link 30:

$${T}_{12} = \frac{( P \cdot {N}_{12} )}{{R}_{12}} \qquad [ 5 ]$$

Comparing calculation results for expressions [4] and [5] relating to total average air time T for communicating a packet over each path permits selecting a communication path that will yield maximum transmission throughput. As illustrated above, for the example of communication between mobile stations MS₁, MS₂, this evaluation requires measurement of performance parameters associated with three relevant links: 30, 40, 42. As pointed out earlier herein, the parameters measured in the illustrative example above are representative only. Other parameters may be measured relating to links 30, 40, 42 to effect an evaluation of relative communication link efficiency, link throughput or one or more other link characteristics for evaluating whether to employ direct link 30 or indirect link (40, 42) for communicating between mobile stations MS₁, MS₂.

Whether to employ direct communication link 32 or indirect communication link (40, 44) between first mobile station MS₁ and third mobile station MSₙ may be decided in a similar manner as described above by calculating a total air time T₁ₙ for indirect communication link (40, 42),
T₁ₙ=T_{1A}+T_{nA} [6]

For comparing with average air time T_{1N} for packets having average packet size P communicated between first mobile station MS₁ and third mobile station MSₙ via direct link 32. Calculations and comparisons are substantially similar to calculations and comparisons in evaluating communications between mobile stations MS₁, MS₂. In order to avoid prolixity in this description a calculation and comparison for evaluating communications between mobile stations MS₁, MSₙ will not be further detailed here.

Other parameters may be employed in evaluating communication links for deciding whether to employ a direct link or an indirect link between two mobile stations in a communication system without departing from the scope of the present invention. Evaluation of communication links for deciding whether to employ a direct link or an indirect link between two mobile stations in a communication system may be carried out at any time. Periodic evaluations may be effected at predetermined time intervals. A new evaluation may be effected when a particular parameter or particular parameters are observed to have attained a predetermined value or values. Other measures or occasions may be employed individually or in combination to establish when a new evaluation of communication links is desired.

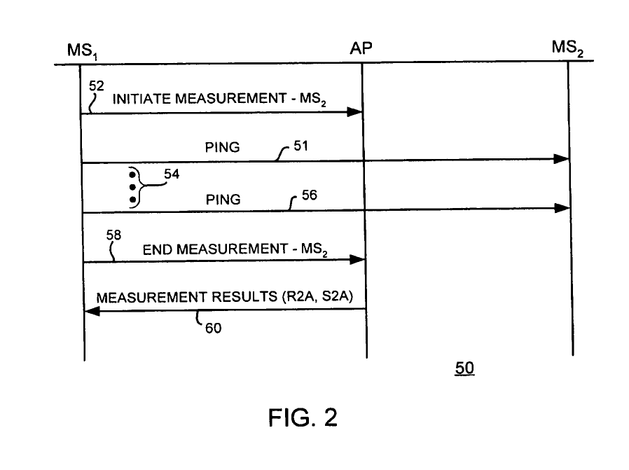

FIG. 2 is a schematic representation of a protocol for the method of the present invention. In FIG. 2, a protocol chart 50 illustrates calls among mobile stations MS₁, MS₂ and an access point AP during a measurement to assess whether a direct link or an indirect link between mobile stations MS₁, MS₂ may be preferred. Protocol chart 50 presumes that mobile station MS₁ may be able to communicate with mobile station MS₂ directly. DLS (Data Link Setup) can be employed to establish whether communication is possible between mobile stations MS₁, MS₂. This means that DLS protocol or another protocol enabling direct links between mobile stations in a Base Station System may be supported by mobile stations MS₁, MS₂ and the involved access point (AP) (e.g., access point 12, FIG. 1). A test message (herein referred to as a “ping” message) may be sent from mobile station MS₁ to mobile station MS₂, as indicated by a line 51. This first ping message 51 may also alert access point AP that a measurement event is commencing. Notification of access point AP of initiation of a measurement event may be effected using a separate message from a ping message as indicated by a line 52. More than one ping message may be required or desired, as indicated by ellipsis 54 and line 56. Another ping message or a separate notification message, indicated by a line 58, may serve to alert access point AP and second mobile station MS₂ that the extant measurement event is ended. An end-measurement message indicated by line 58 may order access point AP to report measured parameters to first mobile station MS₁. Access point AP may also report parameters relating to second mobile station MS₂, as indicated by a line 60. Second mobile station MS₂ may report its parameters directly to first mobile station MS₁.

In this manner, first mobile station MS₁ may establish extant values for parameters such as, by way of example and not by way of limitation:
Throughput R₁₂ and success rate S₁₂ (may be established during one or more ping messages 51, 56);
Throughput R_{1A} and success rate S_{1A} (may be established during one or more ping messages 51, 56 and
Throughput R_{2A} and success rate S_{2A}; throughput R_{2A} and success rate S_{2A} may be established during one or more ping messages 51, 56 and may be passed to first mobile station MS₁ from second mobile station MS₂ or may be passed from access point AP, as indicated by line 60.

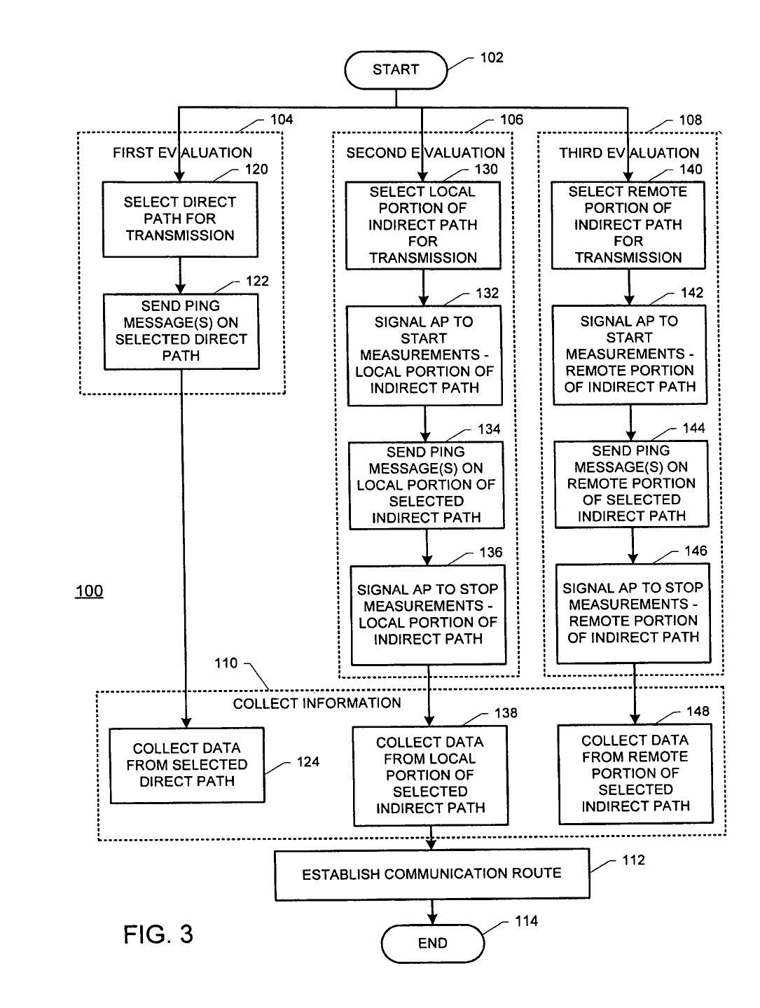

FIG. 3 is a flow chart illustrating the method of the present invention. In FIG. 3, a method 100 effecting communications in a wireless communication network including a plurality of mobile stations and at least one base station may begin at a START locus 102. Method 100 may continue with, in no particular order: (1) operating a first mobile station of the plurality of mobile stations to effect a first evaluation of at least one first parameter relating to quality of a first communication link between the first mobile station and a second mobile station of the plurality of mobile stations, as indicated by a dotted line box 104. (2) operating at least one of the first mobile station and a selected base station of the at least one base station to effect a second evaluation of at least one second parameter relating to quality of a second communication link between the selected base station and the first mobile station, as indicated by a dotted line box 106. (3) operating at least one of the second mobile station and the selected base station to effect a third evaluation of at least one third parameter relating to quality of a third communication link between the selected base station and the second mobile station, as indicated by a dotted line box 108.

Method 100 may continue by collecting information relating to the first evaluation, the second evaluation and the third evaluation at the first mobile station, as indicated by a dotted line box 110.

Method 100 may continue by operating the first mobile station to employ the first evaluation, the second evaluation and the third evaluation to select at least one selected communication link from among the first communication link, the second communication link and the third communication link to establish a communication route between the first mobile station and the second mobile station, as indicated by a block 112. Method 100 terminates at an END locus 114.

The first evaluation 104 may include selecting a path for direct communication transmission from a first mobile station to a second mobile station, as indicated by a block 120. Method 100 may continue from block 120 by sending one or more evaluation messages or ping messages on the direct communication path selected pursuant to block 120, as indicated by a block 122.

The second evaluation 106 may include selecting a local portion of an indirect path—between the first originating mobile station and an access point, as indicated by a block 130. Method 100 may continue from block 130 by signaling the access point in the selected local portion of the indirect path (selected pursuant to block 130) to start measurements of the local portion of the indirect path, as indicated by a block 132. Method 100 may continue from block 132 by sending one or more evaluation messages or ping messages on the local portion of the indirect path selected pursuant to block 130, as indicated by a block 134. Method 100 may continue from block 134 by signaling the access point in the selected local portion of the indirect path to stop measurements of the local portion of the indirect path, as indicated by a block 136.

The third evaluation 108 may include selecting a remote portion of an indirect path—between the access point and a second mobile station, as indicated by a block 140. Method 100 may continue from block 140 by signaling the access point in the selected remote portion of the indirect path (selected pursuant to block 140) to start measurements of the remote portion of the indirect path, as indicated by a block 142. Method 100 may continue from block 142 by sending one or more evaluation messages or ping messages on the remote portion of the indirect path selected pursuant to block 140, as indicated by a block 144. Method 100 may continue from block 144 by signaling the access point in the selected remote portion of the indirect path to stop measurements of the remote portion of the indirect path, as indicated by a block 146.

The collecting indicated by dotted line box 110 may include collecting data relating to the selected direct path evaluated pursuant to dotted line box 104, as indicated by a block 124; collecting data relating to the selected local portion of the indirect path evaluated pursuant to dotted line box 106, as indicated by a block 138; and collecting data relating to the selected remote portion of the indirect path evaluated pursuant to dotted line box 108, as indicated by a block 148. Data collected pursuant to blocks 124, 138, 148 may be employed, by way of example and not by way of limitation, for comparison as described hereinabove in connection with expressions [4] and [5] for selecting a communication path that will yield maximum transmission throughput.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A method effecting communications in a wireless communication network including a plurality of mobile stations and at least one base station; the method comprising:
(a) in no particular order:
(1) operating a first mobile station of said plurality of mobile stations to effect a first evaluation of at least one first parameter relating to quality of a first communication link between said first mobile station and a second mobile station of said plurality of mobile stations;
(2) operating at least one of said first mobile station and a selected base station of said at least one base station to effect a second evaluation of at least one second parameter relating to quality of a second communication link between said selected base station and said first mobile station; and
(3) operating at least one of said second mobile station and said selected base station to effect a third evaluation of at least one third parameter relating to quality of a third communication link between said selected base station and said second mobile station;
(b) collecting information relating to said first evaluation, said second evaluation and said third evaluation at said first mobile station; and
(c) operating said first mobile station to employ said first evaluation, said second evaluation and said third evaluation to select at least one selected communication link from among said first communication link, said second communication link and said third communication link to establish a communication route between said first mobile station and said second mobile station.

2. A method effecting communications in a wireless communication network including a plurality of mobile stations and at least one base station as recited in claim 1 wherein said selected base station effects said second evaluation and said third evaluation.

3. A method effecting communications in a wireless communication network including a plurality of mobile stations and at least one base station as recited in claim 2 wherein said selected base station communicates said information relating to said second evaluation and said third evaluation to said first mobile station.

4. A method effecting communications in a wireless communication network including a plurality of mobile stations and at least one base station as recited in claim 1 wherein said first evaluation, said second evaluation and said third evaluation relate to reliability of said first communication link, said second communication link and said third communication link.

5. A method effecting communications in a wireless communication network including a plurality of mobile stations and at least one base station as recited in claim 4 wherein said first evaluation, said second evaluation and said third evaluation further relate to throughput of said first communication link, said second communication link and said third communication link.

6. A method effecting communications in a wireless communication network including a plurality of mobile stations and at least one base station as recited in claim 4 wherein said selected base station effects said second evaluation and said third evaluation.

7. A method effecting communications in a wireless communication network including a plurality of mobile stations and at least one base station as recited in claim 6 wherein said selected base station communicates said information relating to said second evaluation and said third evaluation to said first mobile station.

8. A method effecting communications in a wireless communication network including a plurality of mobile stations and at least one base station as recited in claim 5 wherein said selected base station effects said second evaluation and said third evaluation.

9. A method effecting communications in a wireless communication network including a plurality of mobile stations and at least one base station as recited in claim 8 wherein said selected base station communicates said information relating to said second evaluation and said third evaluation to said first mobile station.

10. A method effecting communications in a wireless communication network including a plurality of mobile stations and at least one base station; the method comprising:
(a) in no particular order:
(1) operating a first mobile station of said plurality of mobile stations to effect a first evaluation of at least one first parameter relating to quality of at least one first communication link between said first mobile station and at least one second mobile station of said plurality of mobile stations;
(2) operating at least one of said first mobile station and a selected base station of said at least one base station to effect a second evaluation of at least one second parameter relating to quality of a second communication link between said selected base station and said first mobile station; and
(3) operating at least one of said at least one second mobile station and said selected base station to effect a third evaluation of at least one third parameter relating to quality of at least one third communication link between said selected base station and said at least one second mobile station;
(b) collecting information relating to said first evaluation, said second evaluation and said third evaluation at said first mobile station; and
(c) operating said first mobile station to employ said first evaluation, said second evaluation and said third evaluation to select at least one selected communication link from among said first communication link, said second communication link and said at least one third communication link to establish at least one communication route between said first mobile station and said at least one second mobile station.

11. A method effecting communications in a wireless communication network including a plurality of mobile stations and at least one base station as recited in claim 10 wherein said selected base station effects said second evaluation and said third evaluation.

12. A method effecting communications in a wireless communication network including a plurality of mobile stations and at least one base station as recited in claim 11 wherein said selected base station communicates said information relating to said second evaluation and said third evaluation to said first mobile station.

13. A method effecting communications in a wireless communication network including a plurality of mobile stations and at least one base station as recited in claim 10 wherein said first evaluation, said second evaluation and said third evaluation relate to reliability of said first communication link, said second communication link and said at least one third communication link.

14. A method effecting communications in a wireless communication network including a plurality of mobile stations and at least one base station as recited in claim 13 wherein said first evaluation, said second evaluation and said third evaluation further relate to throughput of said first communication link, said second communication link and said at least one third communication link.

15. A method effecting communications in a wireless communication network including a plurality of mobile stations and at least one base station as recited in claim 13 wherein said selected base station effects said second evaluation and said third evaluation.

16. A method effecting communications in a wireless communication network including a plurality of mobile stations and at least one base station as recited in claim 15 wherein said selected base station communicates said information relating to said second evaluation and said third evaluation to said first mobile station.

17. A method effecting communications in a wireless communication network including a plurality of mobile stations and at least one base station as recited in claim 14 wherein said selected base station effects said second evaluation and said third evaluation.

18. A method effecting communications in a wireless communication network including a plurality of mobile stations and at least one base station as recited in claim 17 wherein said selected base station communicates said information relating to said second evaluation and said third evaluation to said first mobile station.

19. A system effecting communications in a wireless communication network including a plurality of mobile stations and at least one base station; the system comprising:
(a) a first evaluation unit coupled with a first mobile station of said plurality of mobile stations; said first evaluation unit effecting a first evaluation of at least one first parameter relating to quality of at least one first communication link between said first mobile station and at least one second mobile station of said plurality of mobile stations;
(b) at least one second evaluation unit coupled with said at least one base station; at least one of said first evaluation unit and said at least one second evaluation unit effecting a second evaluation of at least one second parameter relating to quality of a second communication link between said selected base station and said first mobile station; and
(c) at least one third evaluation unit coupled with said at least one second mobile station; at least one of said at least one second evaluation unit and said at least one third evaluation unit effecting a third evaluation of at least one third parameter relating to quality of at least one third communication link between said selected base station and said at least one second mobile station; said first mobile station collecting information relating to said first evaluation, said second evaluation and said third evaluation; said first mobile station employing said first evaluation, said second evaluation and said third evaluation to select at least one selected communication link from among said first communication link, said second communication link and said at least one third communication link to establish at least one communication route between said first mobile station and said at least one second mobile station.

20. A system effecting communications in a wireless communication network including a plurality of mobile stations and at least one base station as recited in claim 19 wherein said selected base station effects said second evaluation and said third evaluation.

21. A system effecting communications in a wireless communication network including a plurality of mobile stations and at least one base station as recited in claim 20 wherein said selected base station communicates said information relating to said second evaluation and said third evaluation to said first evaluating unit.
